(19) United States
(12) Patent Application Publication
(10) Pub. No.: US 2014/0315373 A1
(43) Pub. Date: Oct. 23, 2014

(54) METHOD FOR MANUFACTURING SILICON CARBIDE SUBSTRATE

(71) Applicant: Sumitomo Electric Industries, Ltd., Osaka (JP)

(72) Inventor: Kyoko OKITA, Itami-shi (JP)

(73) Assignee: Sumitomo Electric Industries, Ltd., Osaka (JP)

(21) Appl. No.: 14/219,061

(22) Filed: Mar. 19, 2014

(30) Foreign Application Priority Data
Apr. 22, 2013 (JP) 2013-089233

(51) Int. Cl. H01L 21/02

(52) U.S. Cl. CPC H01L 21/02378; H01L 21/02041
USPC 438/478

(57) ABSTRACT

A method for manufacturing a silicon carbide substrate 10 has the following steps. A silicon carbide single crystal substrate 1 having a first main surface 1a and a second main surface 1b opposite to the first main surface 1a is prepared. The first main surface 1a is subjected to chemical mechanical polishing. The first main surface 1a is cleaned with an acid containing sulfuric acid. After the step of cleaning with an acid containing sulfuric acid, the first main surface 1a is cleaned with an alkali containing ammonia. Thus, a method for manufacturing a silicon carbide substrate capable of achieving lowered surface roughness of an epitaxial layer can be provided.

### BACKGROUND OF THE INVENTION

1. Field of the Invention

The present invention relates to a method for manufacturing a silicon carbide substrate, and more particularly to a method for manufacturing a silicon carbide substrate including a step of cleaning with an alkali containing ammonia.

2. Description of the Background Art

In recent years, in order to achieve a higher breakdown voltage and lower loss of a semiconductor device and use thereof and the like in an environment at a high temperature, silicon carbide has increasingly been adopted as a material forming a semiconductor device. Since silicon carbide is better in heat conductivity than a nitride semiconductor such as gallium nitride, it is excellent for a substrate for a high-power semiconductor device adapted to a high voltage and a high current.

For example, Japanese Patent Laying-Open No. 2010-4073 describes a method of achieving a concentration of a metal impurity such as iron, nickel, and copper at a surface of silicon carbide, of 1×10¹¹ atoms/cm² or less by cleaning silicon carbide with an acid containing sulfuric acid and a hydrogen peroxide solution.

### SUMMARY OF THE INVENTION

When an epitaxial layer is formed on a surface of a silicon carbide substrate after the silicon carbide substrate is cleaned with the method described in the document above, however, surface roughness of the epitaxial layer is high.

The present invention was made to solve the problem described above, and an object thereof is to provide a method for manufacturing a silicon carbide substrate capable of achieving lowered surface roughness of an epitaxial layer.

The present inventor has studied causes of high surface roughness of an epitaxial layer foamed on a silicon carbide substrate. Consequently, the present inventor has obtained the finding below and discovered the present invention. When a silicon carbide substrate is cleaned with a sulfuric acid-hydrogen peroxide solution, a heavy metal and an organic substance which have adhered to the silicon carbide substrate are effectively removed, however, sulfur (S) remains at the surface of the silicon carbide substrate. When an epitaxial layer of silicon carbide grows on the surface of the silicon carbide substrate at which sulfur remains, in an early stage of epitaxial growth, the epitaxial layer abnormally grows like an island. Consequently, surface roughness of the epitaxial layer becomes high.

A method for manufacturing a silicon carbide substrate according to the present invention has the following steps. A silicon carbide single crystal substrate having a first main surface and a second main surface opposite to the first main surface is prepared. Chemical mechanical polishing is performed on the first main surface. The first main surface is cleaned with an acid containing sulfuric acid. After the step of cleaning with an acid containing sulfuric acid, the first main surface is cleaned with an alkali containing ammonia.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view schematically showing a structure of a silicon carbide substrate in one embodiment of the present invention.

FIG. 2 is a schematic cross-sectional view schematically showing a structure of a variation of the silicon carbide substrate in one embodiment of the present invention.

FIG. 3 is a flowchart for schematically illustrating a method for manufacturing a silicon carbide substrate in one embodiment of the present invention.

FIG. 4 is a flowchart for schematically illustrating a cleaning method in the method for manufacturing a silicon carbide substrate in one embodiment of the present invention.

FIG. 5 is a schematic cross-sectional view schematically showing a surface state of an epitaxial layer formed on the silicon carbide substrate.

### DESCRIPTION OF THE PREFERRED EMBODIMENTS

An embodiment of the present invention will be described hereinafter with reference to the drawings. It is noted that, in the drawings below, the same or corresponding elements have the same reference characters allotted and description thereof will not be repeated. In addition, an individual orientation, a collective orientation, an individual plane, and a collective plane are herein shown in [ ], < >, ( ) and { }, respectively. Moreover, in terms of crystallography, a negative index should be denoted by a number with a bar “-” thereabove, however, a negative sign herein precedes a number.

(1) A method for manufacturing a silicon carbide substrate 10 according to the present embodiment has the following steps. A silicon carbide single crystal substrate 1 having a first main surface 1a and a second main surface 1b opposite to first main surface 1a is prepared. First main surface 1a is subjected to chemical mechanical polishing. First main surface 1a is cleaned with an acid containing sulfuric acid. After the step of cleaning with an acid containing sulfuric acid, first main surface 1a is cleaned with an alkali containing ammonia. As first main surface 1a is cleaned with an alkali containing ammonia, sulfur which has remained at first main surface 1a is effectively removed. Therefore, surface roughness of a surface 2a of an epitaxial layer 2 formed on first main surface 1a is lowered.

(2) In the method for manufacturing silicon carbide substrate 10 according to the present embodiment, preferably, after the step of cleaning with an alkali containing ammonia, silicon carbide epitaxial layer 2 is formed on first main surface 1a. Thus, surface roughness of surface 2a of silicon carbide epitaxial layer 2 formed on the first main surface is lowered.

(3) In the method for manufacturing silicon carbide substrate 10 according to the present embodiment, preferably, the alkali containing ammonia is composed of a solution containing an ammonia aqueous solution, a hydrogen peroxide solution, and ultrapure water. Thus, sulfur which has remained at first main surface 1a can more effectively be removed.

(4) In the method for manufacturing silicon carbide substrate 10 according to the present embodiment, preferably, a volume of ultrapure water is at least 2 times and at most 10 times as large as a volume of the ammonia aqueous solution. If a concentration of ultrapure water is at least 2 times as high as that of the ammonia aqueous solution, sulfur can effectively be removed without using an excessively large amount of ammonia aqueous solution. If a concentration of ultrapure water is at most 10 times as high as that of the ammonia aqueous solution, a concentration of the ammonia aqueous solution to such an extent that sulfur can effectively be removed can be maintained.

(5) In the method for manufacturing silicon carbide substrate 10 according to the present embodiment, preferably, the acid containing sulfuric acid is composed of a solution containing sulfuric acid, a hydrogen peroxide solution, and ultrapure water. Thus, a heavy metal impurity and an organic substance at first main surface 1a can effectively be removed.

(6) In the method for manufacturing silicon carbide substrate 10 according to the present embodiment, preferably, a volume of sulfuric acid is at least 2 times and at most 10 times as large as a volume of a hydrogen peroxide solution. If a volume of sulfuric acid is at least 2 times as large as a volume of the hydrogen peroxide solution, oxidative power for removing a heavy metal impurity and an organic substance is obtained. If a volume of sulfuric acid is at most 10 times as large as a volume of the hydrogen peroxide solution, excessive remain of sulfur at first main surface 1a can be suppressed.

(7) In the method for manufacturing silicon carbide substrate 10 according to the present embodiment, preferably, a ratio of sulfur in composition at first main surface 1a after the step of cleaning with an alkali containing ammonia is lower than 0.5 at %. Thus, silicon carbide substrate 10 low in concentration of sulfur can be obtained.

(8) In the method for manufacturing silicon carbide substrate 10 according to the present embodiment, preferably, a concentration of each of aluminum, iron, nickel, chromium, zinc, and copper as a metal impurity present at first main surface 1a after the step of cleaning with an alkali containing ammonia is not higher than 1×10¹¹ atoms/cm². Thus, silicon carbide substrate 10 with less metal impurity can be obtained.

A construction of a silicon carbide substrate according to one embodiment of the present invention will now be described in further detail.

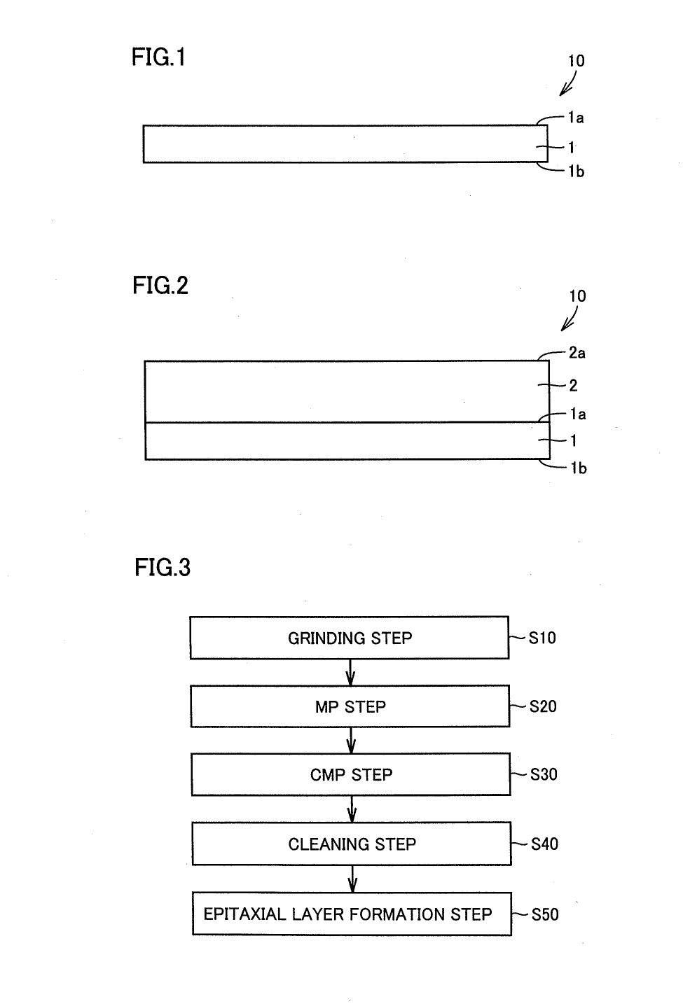

Referring to FIG. 1, silicon carbide substrate 10 in the present embodiment is composed, for example, of a hexagonal silicon carbide single crystal of a poly type 4H and has first main surface 1a and second main surface 1b opposite to the first main surface. Preferably, a concentration of each of aluminum atom, iron atom, nickel atom, chromium atom, zinc atom, and copper atom as a metal impurity present at at least one main surface (for example, first main surface 1a) of first main surface 1a and second main surface 1b is not higher than 1×10¹¹ atoms/cm².

Preferably, a ratio of sulfur atoms in composition at at least one main surface (for example, first main surface 1a) of first main surface 1a and second main surface 1b is lower than 0.5 at %. Arithmetic mean roughness (R^{a}) at at least one main surface (for example, first main surface 1a) of first main surface 1a and second main surface 1b is, for example, 0.1 nm. First main surface 1a of silicon carbide substrate 10 may be, for example, a {000-1} plane or a {0-33-8} plane. First main surface 1a may be a plane off by approximately 8° or smaller from the {000-1} plane. Referring to FIG. 2, silicon carbide substrate 10 may be such a substrate that epitaxial layer 2 composed of silicon carbide is formed on silicon carbide single crystal substrate 1 composed of single crystal silicon carbide.

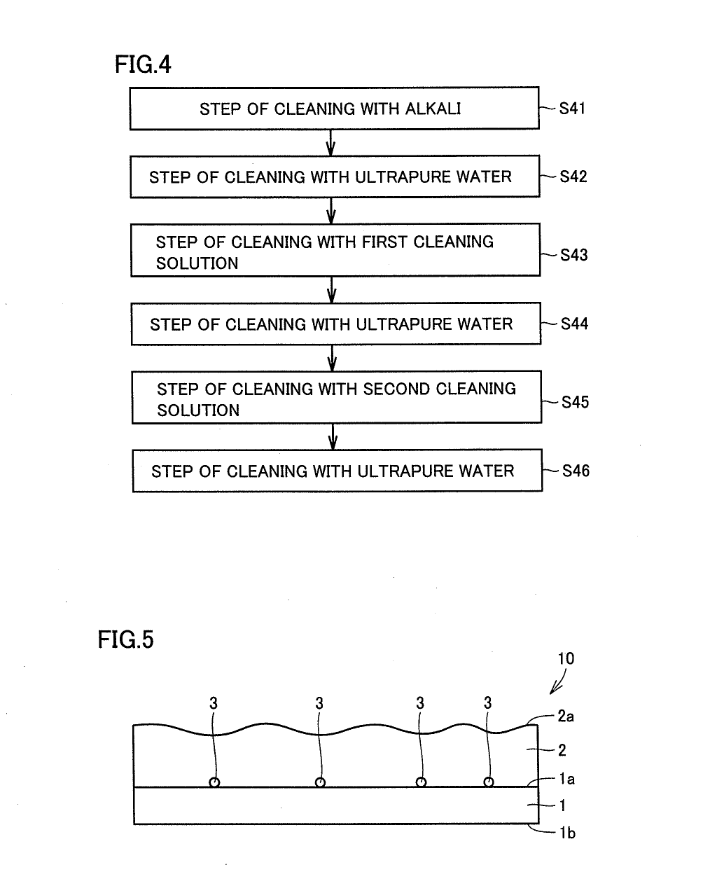

A method for manufacturing a silicon carbide substrate according to one embodiment of the present invention will now be described with reference to FIGS. 3 and 4.

Initially, a seed crystal composed of single crystal silicon carbide and source material powders composed of silicon carbide are arranged in a crucible made, for example, of graphite. Then, silicon carbide is sublimated by heating the source material powders, to thereby recrystallize single crystal silicon carbide on the seed crystal. Here, re-crystallization proceeds, for example, while nitrogen or the like is introduced. Heating is stopped at the time point of growth of a crystal of a desired size on the seed crystal, and the crystal of single crystal silicon carbide is taken out of the crucible. Single crystal silicon carbide is worked to an ingot having a columnar shape. By slicing the ingot, silicon carbide single crystal substrate 1 is cut. Silicon carbide single crystal substrate 1 is composed, for example, of a hexagonal silicon carbide single crystal of a poly type 4H, and has first main surface 1a and second main surface 1b opposite to the first main surface.

Then, a grinding step (S10: FIG. 3) is performed. In the grinding step, main surface 1a of silicon carbide single crystal substrate 1 is subjected to a grinding process, to thereby lower roughness of a cut surface (that is, first main surface 1a). In the grinding process, a diamond grindstone is used as a tool and turned with first main surface 1a of silicon carbide single crystal substrate 1 and the grindstone facing each other and cutting at a constant speed is carried out, so that a surface layer of first main surface 1a of silicon carbide single crystal substrate 1 is removed. Thus, projections and recesses at first main surface 1a of silicon carbide single crystal substrate 1 are removed and first main surface 1a is planarized, so that a thickness of silicon carbide single crystal substrate 1 can be adjusted. A similar grinding step may be performed also on second main surface 1b of silicon carbide single crystal substrate 1.

Then, an MP (Mechanical Polishing) step (S20: FIG. 3) is performed. In an MP process, a solution containing abrasive grains of diamond or the like is used and load is applied to silicon carbide single crystal substrate 1 with first main surface 1a of silicon carbide single crystal substrate 1 facing a surface plate, so that first main surface 1a is polished. By adjusting a grain size of the abrasive grains of diamond or the like, desired surface roughness can be obtained. A metal surface plate made of iron, copper, tin, a tin alloy, or the like, a composite surface plate of a metal and a resin, or a polishing cloth can be used for the surface plate. By employing a hard metal surface plate, a rate can be improved. By employing a soft surface plate, surface roughness can be lowered. A similar MP step may be performed also on second main surface 1b of silicon carbide single crystal substrate 1.

Then, a chemical mechanical polishing step (S30: FIG. 3) is performed. Abrasive grains in CMP should be made of a material softer than silicon carbide in order to lower surface roughness or lessen a process-damaged layer. As abrasive grains in CMP, for example, colloidal silica or fumed silica is employed. A solution in CMP preferably has pH 4 or lower or pH 9.5 or higher in order to enhance a chemical action, and more preferably it has pH 2 or lower and pH 10.5 or higher. pH of a CMP solution can be controlled by adding an inorganic acid such as hydrochloric acid, nitric acid, sulfuric acid, or phosphoric acid, an organic acid such as formic acid, acetic acid, oxalic acid, citric acid, malic acid, tartaric acid, succinic acid, phthalic acid, or fumaric acid, an inorganic alkali such as KOH, NaOH, or NH₄OH, an organic alkali such as choline, amine, or TMAH (tetramethyl ammonium hydroxide), and salts thereof.

Then, a cleaning step (S40: FIG. 3) is performed. In the cleaning step, first main surface 1a of silicon carbide substrate 10 is cleaned, for example, through steps below. Initially, a step of cleaning with an alkali (S41: FIG. 4) is performed. In the step of cleaning with an alkali, for example, TMAH and a surfactant are employed to remove such an abrasive as colloidal silica which has adhered to first main surface 1a of silicon carbide substrate 10 in the CMP step. Then, in a step of cleaning with ultrapure water (S42: FIG. 4), first main surface 1a of silicon carbide substrate 10 is cleaned with ultrapure water to thereby remove TMAH or the like which has remained at first main surface 1a of silicon carbide single crystal substrate 1.

Then, a step of cleaning with a first cleaning solution (S43: FIG. 4) is performed. Specifically, the first cleaning solution as an acid containing sulfuric acid is used to clean first main surface 1a of silicon carbide single crystal substrate 1. The first cleaning solution is, for example, a sulfuric acid-hydrogen peroxide solution composed of a solution containing sulfuric acid, a hydrogen peroxide solution, and ultrapure water. In other words, the first cleaning solution is a solution in which sulfuric acid, the hydrogen peroxide solution, and ultrapure water are mixed. As sulfuric acid, for example, concentrated sulfuric acid of which concentration in percentage by mass is 98% can be used. As the hydrogen peroxide solution, for example, a hydrogen peroxide solution of which concentration in percentage by mass is 30% can be used. As ultrapure water, for example, water of which electric resistivity is not lower than 15 MΩ·cm, total organic carbon (TOC) is lower than 30 ppb, and remaining silica is lower than 10 ppb can be used.

A volume ratio between sulfuric acid, the hydrogen peroxide solution, and ultrapure water contained in the first cleaning solution is, for example, 10 (sulfuric acid):1 (hydrogen peroxide solution):1 (ultrapure water). The volume ratio is preferably from 10 (sulfuric acid):1 (hydrogen peroxide solution):1 (ultrapure water) to 2 (sulfuric acid):1 (hydrogen peroxide solution):1 (ultrapure water). In other words, a volume of sulfuric acid is at least 2 times and at most 10 times as large as a volume of the hydrogen peroxide solution. In addition, a volume of sulfuric acid is at least 2 times and at most 10 times as large as a volume of ultrapure water. Then, in a step of cleaning with ultrapure water (S44: FIG. 4), first main surface 1a of silicon carbide single crystal substrate 1 is cleaned with ultrapure water to thereby remove the sulfuric acid-hydrogen peroxide solution which has remained at first main surface 1a of silicon carbide single crystal substrate 1.

Then, a step of cleaning with a second cleaning solution (S45: FIG. 4) is performed. Specifically, the second cleaning solution as an alkali containing ammonia is used to clean first main surface 1a of silicon carbide single crystal substrate 1. The second cleaning solution is, for example, an ammonia-hydrogen peroxide solution composed of a solution containing an ammonia aqueous solution, a hydrogen peroxide solution, and ultrapure water. In other words, the second cleaning solution is a solution in which the ammonia aqueous solution, the hydrogen peroxide solution, and ultrapure water are mixed. As the ammonia aqueous solution, for example, an ammonia aqueous solution of which concentration in percentage by mass is 28% can be used. As the hydrogen peroxide solution, for example, a hydrogen peroxide solution of which concentration in percentage by mass is 30% can be used. As ultrapure water, for example, water of which electric resistivity is not lower than 15 MΩ·cm, total organic carbon (TOC) is lower than 30 ppb, and remaining silica is lower than 10 ppb can be used.

A volume ratio between the ammonia aqueous solution, the hydrogen peroxide solution, and ultrapure water contained in the second cleaning solution is, for example, 1 (ammonia aqueous solution):1 (hydrogen peroxide solution):5 (ultrapure water). The volume ratio is preferably from 1 (ammonia aqueous solution):1 (hydrogen peroxide solution):10 (ultrapure water) to 1 (ammonia aqueous solution):1 (hydrogen peroxide solution):2 (ultrapure water). In other words, a volume of ultrapure water is at least 2 times and at most 10 times as large as a volume of the ammonia aqueous solution. In addition, a volume of ultrapure water is at least 2 times and at most 10 times as large as a volume of the hydrogen peroxide solution. Then, in a step of cleaning with ultrapure water (S46: FIG. 4), first main surface 1a of silicon carbide substrate 10 is cleaned with ultrapure water to thereby remove the ammonia-hydrogen peroxide solution which has remained at first main surface 1a of silicon carbide single crystal substrate 1.

Preferably, a concentration of sulfur at first surface 1a of silicon carbide substrate 10 after the step of cleaning first main surface 1a of silicon carbide single crystal substrate 1 with the second cleaning solution (an alkali containing ammonia) is lower than 0.5 at %. A concentration of sulfur at first main surface 1a can be measured, for example, with ESCA (Electron Spectroscopy for Chemical Analysis). It is noted that a lower limit value (measurement accuracy) which can be measured with ESCA is, for example, approximately 0.5 at %. In addition, preferably, a concentration of each of aluminum, iron, nickel, chromium, zinc, and copper as a metal impurity present at first main surface 1a of silicon carbide substrate 10 after cleaning of first main surface 1a of silicon carbide single crystal substrate 1 with the second cleaning solution (an alkali containing ammonia) is not higher than 1×10¹¹ atoms/cm². A concentration of each of aluminum, iron, nickel, chromium, zinc, and copper which is present at first main surface 1a can be measured, for example, with ICP-MS (Inductively Coupled Plasma Mass Spectrometry).

Then, an epitaxial layer formation step (S50) is performed. In the epitaxial layer formation step, epitaxial layer 2 composed of silicon carbide is formed on first main surface 1a of silicon carbide single crystal substrate 1. Epitaxial layer 2 contains an impurity such as nitrogen and may have an n type. A thickness of epitaxial layer 2 is, for example, approximately 10 μm, and a concentration of an impurity such as nitrogen is, for example, approximately 5×10¹⁵ cm⁻³.

Referring to FIG. 5, in a case that sulfur atoms 3 are present at first main surface 1a of silicon carbide single crystal substrate 1 (silicon carbide substrate 10), a rate of growth of an epitaxial layer which grows at a position present near sulfur atom 3 is considered to be different from a rate of growth of an epitaxial layer which grows at a position present far from sulfur atom 3. Therefore, it is considered that the epitaxial layer which has grown on a position where sulfur atom 3 is present is different in thickness from the epitaxial layer which has grown on a position where sulfur atom 3 is absent, and projections and recesses at surface 2a of epitaxial layer 2 are great. In other words, by decreasing the number of sulfur atoms 3 present at first main surface 1a of silicon carbide single crystal substrate 1 (silicon carbide substrate 10), planarity of surface 2a of epitaxial layer 2 which grows on first main surface 1a of silicon carbide single crystal substrate 1 (silicon carbide substrate 10) can be improved.

A function and effect of the method for manufacturing a silicon carbide substrate according to the present embodiment will now be described.

The method for manufacturing silicon carbide substrate 10 according to the present embodiment has the following steps. Silicon carbide single crystal substrate 1 having first main surface 1a and second main surface 1b opposite to first main surface 1a is prepared. First main surface 1a is subjected to chemical mechanical polishing. First main surface 1a is cleaned with an acid containing sulfuric acid. After the step of cleaning with an acid containing sulfuric acid, first main surface 1a is cleaned with an alkali containing ammonia. As first main surface 1a is cleaned with the alkali containing ammonia, sulfur which has remained at first main surface 1a is effectively removed. Therefore, surface roughness of surface 2a of epitaxial layer 2 formed on first main surface 1a is lowered.

In addition, according to the method for manufacturing silicon carbide substrate 10 in the present embodiment, after the step of cleaning with an alkali containing ammonia, silicon carbide epitaxial layer 2 is formed on first main surface 1a. Thus, surface roughness of surface 2a of epitaxial layer 2 formed on first main surface 1a is lowered.

Furthermore, according to the method for manufacturing silicon carbide substrate 10 in the present embodiment, the alkali containing ammonia is composed of a solution containing an ammonia aqueous solution, a hydrogen peroxide solution, and ultrapure water. Thus, sulfur which has remained at first main surface 1a can more effectively be removed.

Furthermore, according to the method for manufacturing silicon carbide substrate 10 in the present embodiment, a volume of ultrapure water is at least 2 times and at most 10 times as large as a volume of the ammonia aqueous solution. If a concentration of ultrapure water is at least 2 times as high as that of the ammonia aqueous solution, sulfur can effectively be removed without using an excessively large amount of ammonia aqueous solution. If a concentration of ultrapure water is at most 10 times as high as that of the ammonia aqueous solution, a concentration of the ammonia aqueous solution to such an extent that sulfur can effectively be removed can be maintained.

Furthermore, according to the method for manufacturing silicon carbide substrate 10 in the present embodiment, the acid containing sulfuric acid is composed of a solution containing sulfuric acid, a hydrogen peroxide solution, and ultrapure water. Thus, a heavy metal impurity and an organic substance at first main surface 1a can effectively be removed.

Furthermore, according to the method for manufacturing silicon carbide substrate 10 in the present embodiment, a volume of sulfuric acid is at least 2 times and at most 10 times as large as a volume of a hydrogen peroxide solution. If a volume of sulfuric acid is at least 2 times as large as a volume of the hydrogen peroxide solution, oxidative power for removing a heavy metal impurity and an organic substance is obtained. If a volume of sulfuric acid is at most 10 times as large as a volume of the hydrogen peroxide solution, excessive remain of sulfur at first main surface 1a can be suppressed.

Furthermore, according to the method for manufacturing silicon carbide substrate 10 in the present embodiment, a ratio of sulfur in composition at first main surface 1a after the step of cleaning with an alkali containing ammonia is lower than 0.5 at %. Thus, silicon carbide substrate 10 low in concentration of sulfur can be obtained.

Furthermore, according to the method for manufacturing silicon carbide substrate 10 in the present embodiment, a concentration of each of aluminum, iron, nickel, chromium, zinc, and copper as a metal impurity present at first main surface 1a after the step of cleaning with an alkali containing ammonia is not higher than 1×10¹¹ atoms/cm². Thus, silicon carbide substrate 10 with less metal impurity can be obtained.

### EXAMPLE

In the present example, an experiment for examining relation between surface roughness of surface 2a of epitaxial layer 2 of silicon carbide substrate 10 and a method of cleaning silicon carbide substrate 10 was conducted. Initially, silicon carbide substrate 10 according to a comparative example was prepared with a cleaning method 1 below. Silicon carbide substrate 10 according to the present inventive example was prepared with a cleaning method 2 below. In cleaning method 1, first main surface 1a of silicon carbide single crystal substrate 1 was cleaned with a sulfuric acid-hydrogen peroxide solution, but not with an ammonia-hydrogen peroxide solution. In cleaning method 2, first main surface 1a of silicon carbide single crystal substrate 1 was cleaned with a sulfuric acid-hydrogen peroxide solution and thereafter first main surface 1a of silicon carbide single crystal substrate 1 was cleaned with an ammonia-hydrogen peroxide solution. Specifically, silicon carbide substrate 10 according to the present inventive example was prepared in accordance with the manufacturing method according to the embodiment above. Silicon carbide substrate 10 according to the comparative example was prepared with a manufacturing method similar to the method for manufacturing silicon carbide substrate 10 according to the present inventive example except for not performing the step of cleaning with a second cleaning solution (S45) and the step of cleaning with ultrapure water (S46).

With the method above, silicon carbide substrate 10 with cleaning method 1 and silicon carbide substrate 10 with cleaning method 2 were prepared. Thereafter, a concentration of a metal impurity present at first main surface 1a of each silicon carbide substrate 10 (specifically, aluminum, iron, nickel, chromium, zinc, and copper) was measured. Measurement of a concentration of a metal impurity was conducted with ICP-MS. Results of measurement of a concentration of a metal impurity are shown in Table 1.

TABLE 1

| | Al | Fe | Ni | Cr | Zn | Cu |
|---|---|---|---|---|---|---|
| Cleaning | Not | 3.0 | Not | Not | 0.3 | Not |
| Method 1 | Detected | | Detected | Detected | | Detected |
| Cleaning | Not | 2.0 | Not | Not | 0.2 | Not |
| Method 2 | Detected | | Detected | Detected | | Detected |

[Unit: 1 × 10¹⁰ atoms/cm²]

As shown in Table 1, it was confirmed that iron and zinc were present at each of first main surface 1a of silicon carbide substrate 10 with cleaning method 1 (comparative example) and first main surface 1a of silicon carbide substrate 10 with cleaning method 2 (present inventive example). Presence of each of aluminum (Al), nickel (Ni), chromium (Cr), and copper (Cu) was not detected with ICP-MS. Regarding a concentration of each of iron (Fe) and zinc (Zn), no significant difference was found between silicon carbide substrate 10 according to the comparative example and silicon carbide substrate 10 according to the present inventive example.

Then, a ratio of sulfur in surface composition at first main surface 1a of silicon carbide substrate 10 cleaned with each method of cleaning method 1 and cleaning method 2 was measured. Measurement of a ratio of sulfur was conducted with ESCA. Results of measurement of surface composition at first main surface 1a of silicon carbide substrate 10 according to each of the comparative example and the present inventive example are shown in Table 2.

TABLE 2

| | Si | C | O | S |
|---|---|---|---|---|
| Cleaning | 32.3 | 33.6 | 26.3 | 2.3 |
| Method 1 | | | | |
| Cleaning | 32.7 | 41.6 | 25.6 | Not |
| Method 2 | | | | Detected |

[Unit: %]

As shown in Table 2, presence of silicon (Si), carbon (C), oxygen (O), and sulfur (S) at first main surface 1a of silicon carbide substrate 10 with cleaning method 1 (comparative example) was confirmed. A ratio of sulfur was 2.3 at %. On the other hand, though presence of silicon, carbon, and oxygen at first main surface 1a of silicon carbide substrate 10 with cleaning method 2 (present inventive example) was confirmed, presence of sulfur was not confirmed. Since the lower limit value of measurement with ESCA employed in the present measurement is approximately 0.5 at %, it is considered that a ratio of sulfur is lower than 0.5 at % even if it is present at first main surface 1a of silicon carbide substrate 10 according to the present inventive example. In addition, a ratio of carbon in composition at first main surface 1a of silicon carbide substrate 10 according to the present inventive example was higher than silicon by 5 at % or more.

Then, epitaxial layer 2 was formed on first main surface 1a of silicon carbide substrate 10 manufactured as cleaned with each method of cleaning method 1 and cleaning method 2, and arithmetic mean roughness (Rₐ) which is an indicator of surface roughness at surface 2a of epitaxial layer 2 was measured. Arithmetic mean roughness (Rₐ) was measured with AFM (Atomic Force Microscope). A field of view used for measurement was set to 10 μm×10 μm. Results of measurement of arithmetic mean roughness (Rₐ) of first main surface 1a of silicon carbide substrate 10 according to each of the comparative example and the present inventive example are shown in Table 3.

TABLE 3

| | Ra |
|---|---|
| Cleaning Method 1 | 0.8 |
| Cleaning Method 2 | 0.1 |

[Unit: nm]

As shown in Table 3, arithmetic mean roughness (Rₐ) of surface 2a of epitaxial layer 2 of silicon carbide substrate 10 (comparative example) with cleaning method 1 was 0.8 nm. On the other hand, arithmetic mean roughness (Rₐ) of surface 2a of epitaxial layer 2 of silicon carbide substrate 10 (present inventive example) with cleaning method 2 was 0.1 nm. Namely, it was confirmed that surface 2a of silicon carbide epitaxial layer 2 formed on first main surface 1a of silicon carbide single crystal substrate 1 of which first main surface 1a was cleaned with a sulfuric acid-hydrogen peroxide solution and thereafter cleaned with an ammonia-hydrogen peroxide solution had less projections and recesses than surface 2a of epitaxial layer 2 formed on first main surface 1a of silicon carbide single crystal substrate 1 of which first main surface 1a was cleaned with the sulfuric acid-hydrogen peroxide solution but not with the ammonia-hydrogen peroxide solution (in other words, planarity was better).

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide substrate, comprising the steps of:
preparing a silicon carbide single crystal substrate having a first main surface and a second main surface opposite to said first main surface;
performing chemical mechanical polishing of said first main surface;
cleaning said first main surface with an acid containing sulfuric acid; and
cleaning said first main surface with an alkali containing ammonia after said step of cleaning with an acid containing sulfuric acid.

2. The method for manufacturing a silicon carbide substrate according to claim 1, further comprising the step of forming a silicon carbide epitaxial layer on said first main surface after said step of cleaning with an alkali containing ammonia.

3. The method for manufacturing a silicon carbide substrate according to claim 1, wherein
said alkali containing ammonia is composed of a solution containing an ammonia aqueous solution, a hydrogen peroxide solution, and ultrapure water.

4. The method for manufacturing a silicon carbide substrate according to claim 3, wherein
a volume of said ultrapure water is at least 2 times and at most 10 times as large as a volume of said ammonia aqueous solution.

5. The method for manufacturing a silicon carbide substrate according to claim 1, wherein
said acid containing sulfuric acid is composed of a solution containing sulfuric acid, a hydrogen peroxide solution, and ultrapure water.

6. The method for manufacturing a silicon carbide substrate according to claim 5, wherein
a volume of said sulfuric acid is at least 2 times and at most 10 times as large as a volume of said hydrogen peroxide solution.

7. The method for manufacturing a silicon carbide substrate according to claim 1, wherein
a ratio of sulfur in composition at said first main surface after said step of cleaning with an alkali containing ammonia is lower than 0.5 at %.

8. The method for manufacturing a silicon carbide substrate according to claim 1, wherein
a concentration of each of aluminum, iron, nickel, chromium, zinc, and copper as a metal impurity present at said first main surface after said step of cleaning with an alkali containing ammonia is not higher than 1×10¹¹ atoms/cm².
